(19) United States
(12) Patent Application Publication
(10) Pub. No.: US 2009/0078933 A1
(43) Pub. Date: Mar. 26, 2009

(54) ORGANIC LIGHT EMITTING DEVICE

(75) Inventors: Hongmo Koo, Gumi-city (KR); Daeyang Oh, Seoul (KR); Sangjeon Kim, Gumi-city (KR)

Correspondence Address: KED & ASSOCIATES, LLP, P.O. Box 221200, Chantilly, VA, 20153-1200, US

(73) Assignee: LG Electronics Inc.

(21) Appl. No.: 11/950,046

(22) Filed: Dec. 4, 2007

(30) Foreign Application Priority Data
Sep. 21, 2007 (KR) 10-2007-0097015
Sep. 21, 2007 (KR) 10-2007-0097017

(51) Int. Cl. H01L 51/52

(52) U.S. Cl. 257/40; 257/79; 257/E51.018

(57) ABSTRACT

An organic light emitting device includes a first electrode disposed on a substrate, a plurality of organic function layers disposed on the first electrode and comprising an emitting layer, and a second electrode disposed on the organic function layers. One of the organic layers includes an inorganic material. This layer may be formed adjacent the first electrode or adjacent the second electrode to form top-emission or bottom-emission structures.

This application claims the benefit of Korean Patent Application No. 10-2007-0097015 and 10-2007-0097017 both filed Sep. 21, 2007, the subject matters of which are incorporated herein by reference.

### BACKGROUND

1. Field

One or more embodiments described herein relate to a display device.

2. Background

The importance of flat panel displays has increased with consumer demand for multimedia products and services. One type of flat panel display known as an organic light emitting device (OLED) has high response speed, low power consumption, and a wide viewing angle. In spite of these advantages, OLEDs continue to demonstrate low emission efficiency which makes then unreliable.

### BRIEF DESCRIPTION OF THE DRAWINGS

FIG. 1 is a cross-sectional view of one embodiment of an organic light emitting device.

FIG. 2 is a diagram showing operational features of the organic light emitting device of FIG. 1.

FIG. 3 is a cross-sectional view of another embodiment of an organic light emitting device.

FIG. 4 is a diagram showing operational features of the organic light emitting device in FIG. 3.

FIG. 5 is a cross-sectional view of a third embodiment of an organic light emitting device.

FIGS. 6A to 6C illustrate various implementations of a color image display method in an organic light emitting device according to an exemplary embodiment.

### DETAILED DESCRIPTION

Organic light emitting devices are generally formed from a substrate, a first electrode disposed on the substrate, an organic film disposed on the first electrode, and a second electrode disposed on the organic film. The organic film may include a light-emitting layer, a hole injection layer (HIL), a hole transport layer (HTL), an electron transport layer (ETL), and an electron injection layer (EIL).

When a voltage is applied between the first and second electrodes, holes are injected from the first electrode into the emitting layer through the hole injection layer, and electrons are injected from the second electrode into the emitting layer through the electron injection layer. The holes and electrons combine in the emitting layer to form excitons, and light is emitted when the excitons transfer to ground state.

In order to achieve high emission efficiency, holes and electrons injected into the emitting layer should be well balanced. To this end, the hole injection layer or the hole transport layer in some OLEDs is formed between the first electrode and the emitting layer, and the electron transport layer or the electron injection layer is formed between the emitting layer and the second electrode. This structure is used in an attempt in order to lower the energy barrier between the respective layers and facilitate movement of electrons and holes.

However, in OLEDs of this type, the mobility of holes is generally 10 times faster than that of electrons. Thus, the amount of holes and electrons injected into the emitting layer is different. As a result, emission efficiency is reduced.

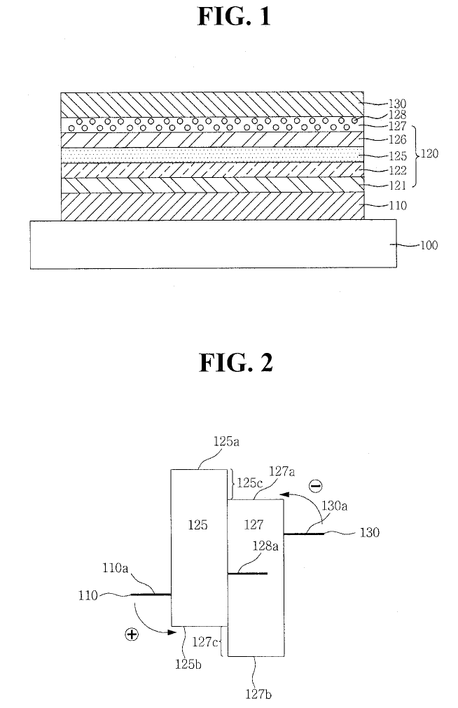

FIG. 1 shows a cross-sectional view of one embodiment of organic light emitting device. This device includes a first substrate 100, a first electrode 110 disposed on the first substrate, and organic function layers 120 respectively comprising a hole injection layer 121, a hole transport layer 122, an emitting layer 125, an electron transport layer 126, and an electron injection layer 127 over the first electrode 110. The device further includes a second electrode 130 disposed on the organic function layers 120.

According to the present embodiment, the electron injection layer 127 adjacent the second electrode 130 includes an inorganic material 128. The inorganic material is preferably dispersed in the electron injection layer.

The first electrode 110 is disposed over the first substrate. At least one thin film transistor (formed from a semiconductor layer, a gate electrode, a source electrode, and a drain electrode) may be disposed between first substrate 100 and first electrode 110. The first substrate may be formed, for example, from insulating glass, plastic or a conductive material.

The first electrode 110 may serve as an anode and may be formed from a transparent electrode or a reflective electrode. If formed from a transparent electrode, electrode 110 may be made of indium tin oxide (ITO), indium zinc oxide (IZO), or zinc oxide (ZnO). If formed from a reflective electrode, electrode 110 may be made of aluminum (Al), silver (Ag) or nickel (Li) under a layer formed of ITO, IZO, or ZnO. Also, a reflection layer may be disposed between two layers formed of ITO, IZO or ZnO. The first electrode may be formed by a sputtering method, an evaporation method, a vapor phase deposition method, or an electron beam deposition method.

The organic function layers 120 are disposed over the first electrode and may comprise emitting layer 125 and at least one selected from a group comprising the hole injection layer 121, the hole transport layer 122, the electron transport layer 126, or the electron injection layer 127. According to one embodiment, all of these layers are included.

The hole injection layer 121 may function to facilitate the injection of holes from first electrode 110 to emitting layer 125. The hole injection layer may be made of copper CuPc (phthalocyanine), PEDOT (poly(3,4)-ethylenedioxythiophene), PANI (polyaniline) or NPD (N,N-dinaphthyl-N,N′-diphenyl benzidine), but other compounds may be used if desired.

The hole injection layer may have a valence band level of −5.0 to −5.5 eV to allow holes to easily move from the first electrode to the emitting layer. The hole injection layer may have a conduction band level of −1.8 to −2.8 eV, and may be formed by an evaporation method or a spin-coating method.

The thickness of the hole injection layer 121 preferably lies within a predetermined range, e.g., from 5 to 150 nm. If the thickness of the hole injection layer is 5 nm or higher, a reduction in a hole injection characteristic can be prevented. If the thickness of the hole injection layer is 50 nm or less, an increase in driving voltage can be prevented. The driving voltage may be used to increase the movement of holes when the thickness of the hole injection layer 121 is too thick.

A buffer layer may be disposed between first electrode 110 and hole injection layer 121. The buffer layer may comprise a compound containing an oxalic acid radical —OH, a cyanogen radical —CN or a halogen radical having a strong electron affinity. As an example, the buffer layer may comprise a compound having the following chemical equation:

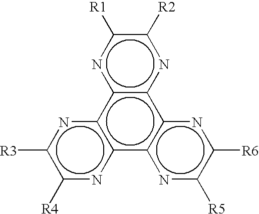

where one or more of R1 to R6 may comprise an oxalic acid radical —OH, a cyanogen radical —CN, and a halogen radical. The buffer layer may function to stabilize the interface and may comprise a material having a strong electron affinity, thus pulling electrons existing in the hole injection layer 121 into the buffer layer.

A relatively large amount of holes may therefore be generated in the hole injection layer 121. The holes may be transferred to the hole transport layer, and the emitting layer is therefore supplied with a sufficient amount of holes. Accordingly, the buffer layer can stabilize the interface and generate holes in the hole injection layer so that the driving voltage can be lowered.

According to one embodiment, the difference between the conduction band level and the valence band level of the buffer layer may fall within ±5 eV. If the difference between the conduction band level and the valence band level of the buffer layer is −0.5 eV or higher, the occurrence of hole trapping in which holes are not moved from the first electrode to the hole injection layer can be prevented.

The buffer layer may have a thickness of 10 to 100 angstrom. If the thickness of the buffer layer is 10 angstrom or more, the interface between the first electrode and the hole injection layer can be stabilized. If the thickness of the buffer layer is 100 angstrom or less, hole can move easily from the first electrode to the hole injection layer.

The hole transport layer 122 functions to smoothly transport holes. The hole transport layer 122 may be made of NPD(N,N-dinaphthyl-N,N′-diphenyl benzidine), TPD(N,N′-bis-(3-methylphenyl)-N,N′-bis-(phenyl)-benzidine, s-TAD and MTDATA(4,4′,4″-Tris(N-3-methylphenyl-N-phenyl-amino)-triphenylamine), but not limited thereto. The hole transport layer may have a valence band level of −5.0 to −5.8 eV and a conduction band level of −1.8 to −3.0 eV so that holes can be easily moved to the emitting layer. Further, the hole transport layer may be formed by an evaporation method or a spin-coating method.

The hole transport layer may also have a thickness of 5 to 150 nm. If the thickness of the hole transport layer is 5 nm or more, a reduction in a hole transport characteristic can be prevented. If the thickness of the hole transport layer is 150 nm or less, an increase in the driving voltage, which is applied in order to increase movement of holes when the thickness of the hole transport layer is too thick, can be prevented.

The hole transport layer 122 may also function to prevent metal within the buffer layer from diffusing into the emitting layer, in the event that the buffer layer is comprised of a metal compound.

The emitting layer 125 may be made of a material that emits red, green, or blue color light. This material may include a phosphorescence or fluorescent material.

In the case where the emitting layer is to emit red light, the emitting layer may be made of a phosphorescence material having a host material comprising CBP (carbazole biphenyl) or mCP(1,3-bis(carbazol-9-yl)) and a dopant comprising at least one selected from a group comprising PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), or PtOEP(octaethylporphyrin platinum). Alternately, the emitting layer may be made of a fluorescent material comprising PBD:Eu(DBM)3(Phen) or Perylene, but not limited thereto.

Also, in the case where the emitting layer is to emit red light, the valence band level and the conduction band level of the host material may range from −5.0 to −6.5 eV and −2.0 to −3.5 eV, respectively. Further, the valence band level and the conduction band level of the dopant material may range from −4.0 to −6.0 eV and −2.4 to −3.5 eV, respectively. The conduction band level of the host material may comprise the conduction band level of the dopant material.

In the case where the emitting layer is to emit green light, the emitting layer may be made of a phosphorescence material that contains a host material comprising CBP or mCP and a dopant material comprising Ir(ppy)3(fac tris(2-phenylpyridine)iridium). Alternately, the emitting layer may be made of a fluorescent material comprising, for example, Alq3(tris(8-hydroxyquinolino)aluminum), but not limited thereto.

Also, in the case where the emitting layer is to emit green light, the valence band level and the conduction band level of the host material may range from −5.0 to −6.5 eV and −2.0 to −3.5 eV, respectively. Furthermore, the valence band level and conduction band level of the dopant material may range from −4.5 to −6.0 eV and −2.0 to −3.5 eV, respectively. The conduction band level of the host material may comprise the conduction band level of the dopant material.

In the case where the emitting layer is to emit blue light, the emitting layer may be made of a phosphorescence material having a host material comprising CBP or mCP and a dopant material comprising 4,6-F2 ppy2Irpic. Alternately, the emitting layer may be made of a fluorescent material comprising any one selected from a group comprising spiro-DPVBi, spiro-6P, distylbenzene (DSB), distrylarylene (DSA), PFO-based polymer, or PPV-based polymer, but not limited thereto.

Also, in the case where the emitting layer is to emit blue light, the valence band level and conduction band level of the host material may range from 5.0 to 6.5 eV and −2.0 to −3.5 eV, respectively. Furthermore, the valence band level and conduction band level of the dopant material may range from −4.5 to −6.0 eV and −2.0 to −3.5 eV, respectively. The conduction band level of the host material may comprise the conduction band level of the dopant material.

The electron transport layer 126 functions to facilitate the transportation of electrons. The electron transport layer may be formed from Alq3(tris(8-hydroxyquinolino)aluminum, PBD, TAZ, spiro-PBD, Balq, or Salq, but not limited thereto. Also, the electron transport layer 126 may have a valence band level of −5.0 to −6.5 eV and a conduction band level of −2.5 to −3.8 eV so that, for example, electrons can easily move from the second electrode 130 to the emitting layer. The electron transport layer may be formed by an evaporation method or a spin-coating method.

Further, according to one embodiment, the electron transport layer may have a thickness of 1 to 50 nm. If the thickness of the electron transport layer is 1 nm or more, a reduction in a electron transport characteristic can be prevented. If the thickness of the electron transport layer is 50 nm or less, an increase in driving voltage, applied in order to increase movement of electrons when the thickness of the electron transport layer 126 is too thick, can be prevented.

The electron transport layer 126 may also function to prevent holes, injected from the first electrode, from moving to the second electrode through the emitting layer. In other words, the electron transport layer 126 serves as a hole stop layer, which facilitates the coupling of holes and electrons in the emitting layer.

The electron injection layer 127 functions to facilitate the injection of electrons and may be made of Alq3(tris(8-hydroxyquinolino)aluminum), PBD, TAZ, spiro-PBD, BAlq, or SAlq, but not limited thereto. According to the present embodiment, the electron injection layer includes inorganic material 128, which may be made of a metal compound such as, for example, an alkali metal or alkaline earth metal. A metal compound comprising an alkali metal or an alkaline earth metal may comprise at least one selected from a group comprising LiQ, TiF, NaF, KF, RbF, CsF, FrF, BeF₂, MgF₂, CaF₂, SrF₂, BaF₂, or RaF₂, but not limited thereto.

The electron injection layer may have a valence band level of 5.0 to −6.5 eV and a conduction band level of −2.5 to −3.5 eV so that electrons can easily move to the emitting layer. The highest level of the valence band of the electron injection layer may be lower than or the same as the highest level of the valence band of electron transport layer 126, and the lowest level of the conduction band of electron injection layer 127 may be lower than or the same as the lowest level of the conduction band of electron transport layer 126.

In the event that the electron transport layer 126 is not formed, the highest level of the valence band of the electron injection layer may be lower than or the same as the highest level of the valence band of emitting layer 125, and the lowest level of the conduction band of the electron injection layer may be lower than or the same as the lowest level of the conduction band of emitting layer 125.

Further, the highest level of the valence band of the electron injection layer may be higher than or the same as the highest level of the valence band of the second electrode (i.e., the cathode electrode), and the lowest level of the conduction band of the electron injection layer may be higher than the highest level of the valence band of the cathode electrode.

The inorganic material 128 may have a conduction band level and a valence band level of −2.0 to −4.0 eV.

As described above, in accordance with one embodiment, the electron injection layer includes an inorganic material. The highest level of the valence band of the inorganic material may be higher than the highest level of the valence band of the organic function layer comprising the inorganic material.

Further, the highest level of the valence band of the inorganic material may be higher than the highest level of the valence band of the remaining organic function layers other than the organic function layer comprising the inorganic material, and the highest level of the valence band of the inorganic material may be lower than the lowest level of the conduction band of the remaining organic function layers other than the organic function layer comprising the inorganic material 128.

The electron injection layer 127 may be formed from an organic material and an inorganic material constituting the electron injection layer by a vacuum deposition method.

Moreover, the electron injection layer may have a thickness of 1 to 50 nm. If the thickness of the electron injection layer is 1 nm or more, there is an advantage in that a reduction in an electron injection characteristic can be prevented. If the thickness of the electron injection layer is 50 nm or less, there is an advantage in an increase in driving voltage, applied in order to increase the movement of electrons when the thickness of the electron injection layer is too thick, can be prevented.

In accordance with one or more embodiments, the electron injection layer 127 comprising inorganic material 128 may be thinner than that of any one (i.e., hole injection layer 121, hole transport layer 122, emitting layer 125, electron transport layer 126) of the remaining organic function layers except for the electron injection layer 127.

In other words, the mobility of holes injected from the first electrode 110 may be 10 times faster than that of electrons injected from the second electrode 130. Thus, if the thickness of the electron injection layer 127 is thinner than that of other layers, electrons injected from the second electrode 130 can move fast because the thickness of the electron injection layer 127 is thin, so that holes and charges can be balanced. Accordingly, excitons can be formed uniformly in the emitting layer 125, improving emission efficiency.

Also, in the foregoing embodiment, the electron injection layer 127 may include an inorganic material 128. This inorganic material may be dispersed in the electron injection layer. Furthermore, the electron injection layer may be formed of an organic material and an inorganic material by a vacuum deposition method.

A mixture ratio of the organic material and the inorganic material may be 2:1 to 10:1. If the mixture ratio of the organic material and the inorganic material is 2:1 or more, mobility of electrons injected from the second electrode to the emitting layer can be improved. If the mixture ratio of the organic material and the inorganic material is 10:1 or less, the ratio of the inorganic material within the electron injection layer is decreased, thereby improving the mobility of electrons.

The inorganic material within electron injection layer 127 may be dispersed uniformly. A gap between particles of the inorganic material dispersed in the electron injection layer 127 may range from 5 to 45 angstrom.

If the gap between particles of the inorganic material is 5 angstrom or more, the inorganic material may serve as a barrier (i.e., an insulating film) in a path along which electrons move, so that it can prevent that the movement of electrons is hindered. If the gap between particles of the inorganic material 128 is 45 angstrom or less, there is an advantage in that it can prevent a problem that hopping of electrons becomes difficult.

Further, the electron injection layer comprising the inorganic material may cause the valence band level of the inorganic material to be lower than the conduction band level of the organic material forming the electron injection layer. Thus, the inorganic material within the electron injection layer facilitates hopping of electrons injected from the second electrode to the emitting layer, so that holes and electrons injected into the emitting layer are balanced. Accordingly, emission efficiency can be improved.

The second electrode 130 may be a cathode electrode and may be made of magnesium (Mg), calcium (Ca), aluminum (Al), silver (Ag), or an alloy of them having a low work function.

When an organic light emitting device has a front or both-side light-emitting structure, second electrode 130 can be formed to a thin thickness to the extent that light can pass therethrough. When an organic light emitting device has a rear light-emitting structure, the second electrode can be formed to a thick thickness to the extent that light can be reflected therefrom.

In accordance with one embodiment, a structure in which both the electron transport layer 126 and the electron injection layer 127 are formed between the emitting layer 125 and the second electrode 130 (for example, an organic light emitting device in which the inorganic material 128 is comprised in the electron injection layer 127, which is the closest to the second electrode 130, of the emitting layer 125, the electron transport layer 126, and the electron injection layer 127) has been described.

Alternately, in the event the electron injection layer is not between the emitting layer and the second electrode, the inorganic material may be included in the electron transport layer (i.e., the organic function layer, which is the closest to the second electrode).

FIG. 2 shows how the organic light emitting device of the first embodiment operates. In this figure, left and right directions indicate the location of a stack direction of the organic light emitting device, and up and down directions indicate energy levels of the conduction band and the valence band of each layer material.

Referring to FIG. 2, the device includes the first electrode 110, the emitting layer 125, the electron injection layer 127, and the second electrode 130. A fermi level 110a is shown in the first electrode, and a lowest level of a conduction band 125a and a highest level of a valence band 125b are shown in the emitting layer 125. Also, a lowest level of the conduction band 127a and a highest level of the valence band 127b are shown in the electron injection layer 127, and a fermi level 130a is shown in the second electrode 130.

The lowest level of the conduction band 125a of the emitting layer 125 is higher than the lowest level of the conduction band 127a of the electron injection layer 127. Thus, in order for electrons injected from the second electrode 130 to move toward the emitting layer 125, the electrons have to cross an energy band gap 125c.

The highest level of the valence band 127b of the electron injection layer 127 is lower than the highest level of the valence band 125b of the emitting layer 125. Thus, in order for holes injected from the first electrode 110 to move toward the electron injection layer 127, the holes have to cross an energy band gap 127c.

In accordance with this embodiment, the organic light emitting device comprises an organic function layer adjacent to the second electrode. In this layer, an inorganic material having a valence band highest level 128a higher than the valence band highest level 127b of the electron injection layer 127 is included, so that movement of electrons is facilitated.

In other words, the inorganic material has valence band highest level 128a higher than the highest level of the valence band 127b of the electron injection layer 127, but which is lower than the lowest level of the conduction band 127a of the electron injection layer 127. Accordingly, the highest level of the valence band 128a of the inorganic material is lower than a high conduction band lowest level 127a of the electron injection layer 127, so that hopping of electrons can be facilitated.

Further, the highest level of the valence band 128a of the inorganic material may be higher than the highest level of the valence band 125b of the emitting layer 125, but lower than the lowest level of the conduction band 125a of the emitting layer 125. Furthermore, the highest level of the valence band 128a of the inorganic material may be lower than the lowest level of the conduction band of the host material of the emitting layer, but higher than the highest level of the valence band of the host material of the emitting layer.

Also, the highest level of the valence band 128a of the inorganic material may be lower than the lowest level of the conduction band of the dopant material of the emitting layer, but higher than or the same as the highest level of the valence band of the dopant material of the emitting layer.

Though not shown in FIG. 2, if the electron transport layer is between emitting layer 125 and electron injection layer 127, the highest level of the valence band 128a of the inorganic material may be higher than the highest level of the valence band of the electron transport layer, but lower than the lowest level of the conduction band of the electron transport layer.

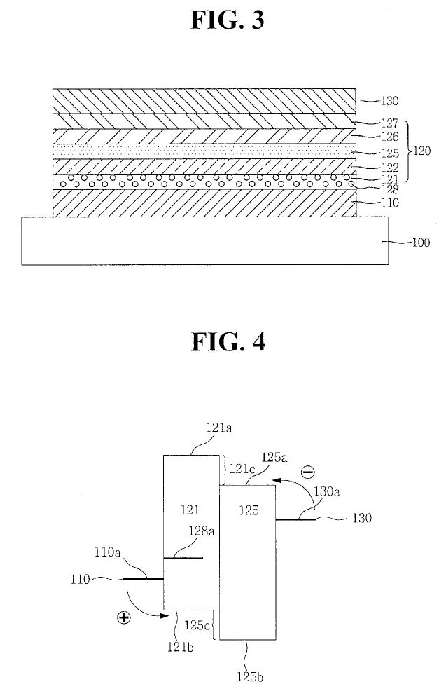

As shown in FIG. 3, in accordance with a second embodiment an organic light emitting device includes an inorganic material 128 in the hole injection layer 121, which is located adjacent the first electrode. Description of the first electrode, the hole transport layer, the emitting layer, the electron transport layer, and the electron injection layer, which overlap those like in the first embodiment, is omitted.

More specifically, as shown in FIG. 3, a cross-sectional view of the organic light emitting device of the second embodiment includes first substrate 100, first electrode 110 disposed over the first substrate 100, and organic function layers 120 which include a hole injection layer 121, hole transport layer 122, emitting layer 125, electron transport layer 126, and electron injection layer 127 disposed over the first electrode. The device further includes a second electrode 130 disposed over the organic function layers 120.

The hole injection layer 121 adjacent the first electrode includes an inorganic material 128, which may be dispersed in the hole injection layer 121. The hole injection layer may be made of any one selected from a group comprising CuPc(cupper phthalocyanine), PEDOT(poly(3,4)-ethylenedioxythiophene), PANI(polyaniline) or NPD(N,N-dinaphthyl-N,N′-diphenyl benzidine), but not limited thereto.

The inorganic material 128 may include a metal compound such as an alkali metal or an alkaline earth metal. A metal compound comprising an alkali metal or an alkaline earth metal may comprise at least one selected from a group comprising LiQ, LiF, NaF, KF, RbF, CsF, FrF, BeF₂, MgF₂, CaF₂, SrF₂, BaF₂, or RaF₂, but not limited thereto.

The hole injection layer 121 may have a valence band level of −5.0 to −5.5 eV and a conduction band level of −1.8 to −2.8 eV so that holes can easily move from first electrode 110 to the emitting layer. The highest level of a valence band of the hole injection layer may be higher than or the same as the highest level of a valence band of the hole transport layer 122, and the lowest level of a conduction band of the hole injection layer may be higher than or the same as the lowest level of a conduction band of the hole transport layer 122.

When the hole transport layer is not formed, the highest level of the valence band of the hole injection layer 121 may be higher than or the same as the highest level of a valence band of the emitting layer 125, and the lowest level of the conduction band of the hole injection layer 121 may be higher than or the same as the lowest level of a conduction band of the emitting layer 125.

Further, the highest level of the valence band of the hole injection layer may be lower than or the same as the highest level of a valence band of the first electrode (i.e., an anode electrode), and the lowest level of the conduction band of the hole injection layer 121 may be higher than the highest level of the valence band of the anode electrode.

The inorganic material 128 may have a valence band level and a conduction band level of −2.0 to −4.0 eV.

The hole injection layer 121 may be formed of an organic material and an inorganic material, constituting the hole injection layer 121, by a vacuum deposition method. Also, the hole injection layer may have a thickness in a predetermined range, e.g., 1 to 50 nm. If the thickness of the hole injection layer is 1 nm or more, a reduction in a hole injection characteristic can be prevented. If the thickness of the hole injection layer 121 is 50 nm or less, an increase in driving voltage, applied in order to increase the movement of holes when the thickness of the hole injection layer is too thick, can be prevented.

In accordance with the second embodiment, the thickness of the hole injection layer comprising the inorganic material may be thicker than that of any one (i.e., the hole transport layer 122, emitting layer 125, electron transport layer 126 or electron injection layer 127) of the remaining organic function layers except for the hole injection layer 121.

In other words, mobility of holes injected from the first electrode is 10 times or more faster than that of electrons injected from the second electrode. Thus, if the hole injection layer is thicker than that of other layers, holes injected from the first electrode can lower the mobility of holes since the hole injection layer is thick, so that holes and charges can be balanced. Accordingly, excitons can be formed uniformly in the emitting layer, improving emission efficiency.

In the second embodiment, the hole injection layer 121 may comprise the inorganic material and the inorganic material may be dispersed in the hole injection layer. A gap between particles of the inorganic material dispersed in the hole injection layer 121 may range from 5 to 45 angstrom.

If the gap between particles of the inorganic material is 5 angstrom or more, the inorganic material may serve as a barrier (i.e., an insulating film) in a path along which holes are moved, preventing a reduction in mobility of holes. If the gap between particles of the inorganic material is 45 angstrom or less, a problem that the balance of holes and electrons combined in the emitting layer is difficult can be prevented since the mobility of holes is too high.

The hole injection layer 121 may be formed of the organic material and the inorganic material, constituting the hole injection layer, by a vacuum deposition method.

A mixture ratio of the organic material and inorganic material may be 2:1 to 10:1. If the mixture ratio of the organic material and the inorganic material is 2:1 or more, the mobility of holes injected from the first electrode to the emitting layer can be lowered, so that holes and electrons combined in the emitting layer can be balanced.

If the mixture ratio of the organic material and the inorganic material is 10:1 or less, the ratio of the inorganic material within the hole injection layer can be decreased, preventing a problem that the balance of holes and electrons combined in the emitting layer is difficult because the mobility of holes is difficult to lower.

The highest level of the valence band of the inorganic material 128 may be higher than the highest level of the valence band of the organic function layer comprising the inorganic material. Further, the highest level of the valence band of the inorganic material may be higher than the highest level of the valence band of the remaining organic function layers of the organic function layers except for the organic function layer comprising the inorganic material.

The hole injection layer 121 comprising the inorganic material 128 may cause the valence band level of the inorganic material 128 to lower the valence band level of the organic material constituting the hole injection layer 121. Thus, inorganic material 128 within the hole injection layer 121 may reduce mobility of holes injected from the first electrode to the emitting layer, so that holes and electrons injected into the emitting layer can be balanced to improve emission efficiency.

Also, in the second embodiment, a structure in which both the hole transport layer 122 and the hole injection layer 121 are formed between the emitting layer 125 and the first electrode 110 (for example, an organic light emitting device in which the inorganic material 128 is included in the hole injection layer 121, which is the closest to the first electrode 110, of the emitting layer 125, the hole transport layer 122, and the hole injection layer 121) has been described.

Alternately, in the event that the hole injection layer is not formed between the emitting layer and the first electrode, the inorganic material may be included in the electron transport layer (i.e., the organic function layer, which is the closest to the first electrode).

FIG. 4 is a conceptual view illustrating operation of the second embodiment of the organic light emitting device. In FIG. 4, left and right directions indicate the location of a stack direction of the organic light emitting device, and up and down directions indicate energy levels of the conduction band and the valence band of each layer material.

Referring to FIG. 4, there are disposed a first electrode 110, hole injection layer 121, emitting layer 125, and second electrode 130. A fermi level 110a is shown in the first electrode 110, and a conduction band lowest level 121a and a highest level of the valence band 121b are shown in the hole injection layer 121. A lowest level of the conduction band 125a and a highest level of the valence band 125b are shown in the emitting layer 125, and a fermi level 130a is shown in the second electrode 130.

The lowest level of the conduction band 125a of the emitting layer 125 is lower than the lowest level of the conduction band 121a of the hole injection layer 121. Thus, in order for electrons injected from the second electrode to move toward the first electrode, the electrons have to cross an energy band gap 121c.

Further, the highest level of the valence band 121b of the hole injection layer 127 is higher than the highest level of the valence band 125b of the emitting layer 125. Thus, in order for holes injected from the first electrode to move toward the emitting layer, the holes have to cross an energy band gap 125c.

In accordance with the second embodiment, the organic light emitting device includes an organic function layer adjacent the first electrode that has an inorganic material having a highest level of the valence band 128a higher than the highest level of the valence band 121b of the hole injection layer 121, so that mobility of the holes can be decreased.

In other words, the organic light emitting device comprises the inorganic material having the highest level of the valence band 128a, which is higher than the highest level of the valence band 121b of the hole injection layer 121, but lower than the lowest level of the conduction band 121a of the hole injection layer 121. Accordingly, the highest level of the valence band 128a of the inorganic material causes to lower a high conduction band lowest level 121a of the hole injection layer 121, so that the mobility of holes can be decreased.

Further, the highest level of the valence band 128a of the inorganic material may be higher than the highest level of the valence band 125b of the emitting layer 125, but lower than the lowest level of the conduction band 125a of the emitting layer. Furthermore, the highest level of the valence band 128a of the inorganic material may be lower than the lowest level of the conduction band of a host material of the emitting layer, but higher than the highest level of the valence band of the host material of the emitting layer.

Also, the highest level of the valence band 128a of the inorganic material may be lower than the lowest level of the conduction band of a dopant material of the emitting layer 125, but higher than or the same as the highest level of the valence band of the dopant material of the emitting layer.

Though not shown in FIG. 4, if the hole transport layer is between the emitting layer and hole injection layer, the highest level of the valence band 128a of the inorganic material may be higher than the highest level of the valence band of the hole transport layer, but lower than the lowest level of the conduction band of the hole transport layer.

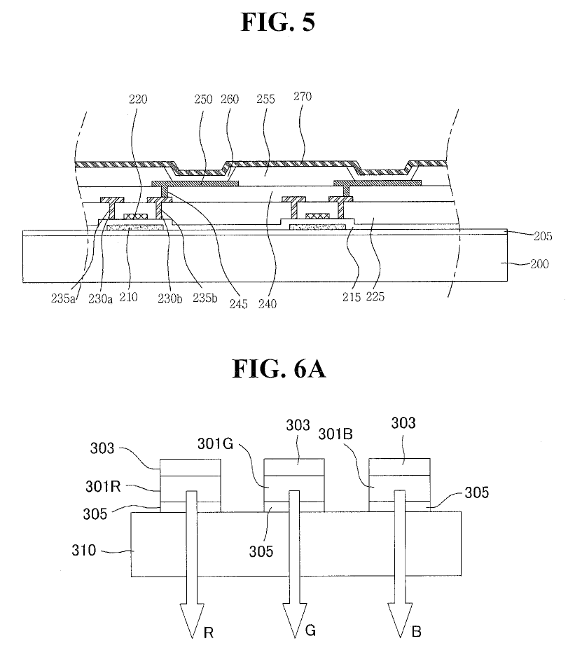

FIG. 5 is a cross-sectional view of a third embodiment of an organic light emitting device. This embodiment includes a buffer layer 205 formed on a substrate. The buffer layer functions to protect a thin film transistor from impurities such as alkali ions drained from the substrate in a subsequent process, and may be formed selectively by using silicon oxide (SiO₂) or silicon nitride (SiNₓ).

Semiconductor layers 210 are formed on the buffer layer. The semiconductor layers may be made of amorphous silicon or polycrystalline silicon, which has been crystallized from amorphous silicon. Though not shown in the drawing, each semiconductor layer 210 may comprise a channel region, a source region, and a drain region. The source region and drain region may be doped with a P or N type impurity.

A gate insulating film 215 is disposed on the substrate 200 comprising the semiconductor layers 210. The gate insulating film 215 may be formed selectively by using silicon oxide (SiO₂) or silicon nitride (SiNₓ).

A gate electrode 220 is formed on a specific region (i.e., the gate insulating film 215 corresponding to the channel region) of the semiconductor layers 210.

The gate electrode 220 may comprise at least one of aluminum (Al), Al alloy, titanium (Ti), silver (Ag), molybdenum (Mo), Mo alloy, tungsten (W), or tungsten silicide (WSi₂), but not limited thereto.

An interlayer insulating film 225 is disposed on the substrate 200 comprising the gate electrode 220. The interlayer insulating film 225 may be an organic film, an inorganic film or a complex film thereof.

When the interlayer insulating film 225 is an inorganic film, it may comprise silicon oxide (SiO₂), silicon nitride (SiNₓ) or silicate on glass (SOG). When the interlayer insulating film 225 is an organic film, it may comprise acrylic-based resin, polyimide-based resin, benzocyclobutene (BCB)-based resin, but not limited thereto.

Contact holes 230a, 230b through which the semiconductor layer 210 is partially exposed are formed to penetrate the interlayer insulating film 225 and the gate insulating film 215.

A source electrode 235a and a drain electrode 235b, which are electrically connected to the semiconductor layers 210 through the contact holes 230a, 230b, are disposed on the substrate 200 comprising the contact holes 230a, 230b.

Each of the source electrode 235a and the drain electrode 235b may comprise a low-resistant material so as to lower wiring resistance, and may have a multi-layer comprised of molybdenum (Mo), molly tungsten (MoW), titanium (Ti), aluminum (Al) and Al alloy. The multi-layer may have a stack structure of Ti/Al/Ti, Mo/Al/Mo or MoW/Al/MoW.

A planarization film 240 is formed on the source electrode 235a and the drain electrode 235b. The planarization film 240 may comprise an organic material, such as benzocyclobutene (BCB)-based resin, acrylic-based resin or polyimide resin, but not limited thereto.

A first electrode 250 electrically connected to the drain electrode 235b through a via hole 245 formed in the planarization film 240 is disposed. The first electrode 250 may be an anode, and may comprise a transparent conductive layer, such as ITO or IZO. Alternately, the first electrode 250 may have a stack structure further comprising a reflection film, such as ITO/Ag/ITO or ITO/Ag, under the transparent conductive layer.

A bank layer 255 through which some parts of the first electrode 250 are exposed is disposed on the substrate 200 having the first electrode 250 formed thereon. The bank layer 250 may comprise an organic material, such as benzocyclobutene (BCB)-based resin, acrylic-based resin or polyimide resin, but not limited thereto.

An organic function layer 260 is formed on the first electrode 250 exposed by the bank layer 255. The organic function layer 260 may be comprised of an organic material, the organic function layer 260 may comprise at least light-emitting layer, and an electron injection layer, an electron transport layer, a hole transport layer or a hole injection layer may be further comprised over or under the emitting layer.

The organic function layer 260 may have the inorganic material comprised in the electron injection layer as in the first embodiment. Alternately, the organic function layer 260 may have the inorganic material comprised in the hole injection layer as in the second embodiment. Description of the organic function layer 260 is the same as that of the above embodiments, and will not be thus given.

A second electrode 270 is disposed on the substrate 200 comprising the organic function layer 260. The second electrode 270 may be a cathode for supplying the organic function layer 260 with electrons, and may comprise Mg, Ag, Ca, Al or an alloy thereof.

Examples of the organic light emitting device according to embodiments described herein are disclosed below. It is to be noted that the following experimental examples are only examples of the embodiments described herein, which, and this document is not limited by the following experimental and these embodiments are not to be limited by the following examples.

### EXPERIMENTAL EXAMPLE 1

ITO having a thickness of 130 nm, as the first electrode, was disposed on the substrate. NPD(4,4′-bis[N-(1-naphthyl)-N-phenyl-amino]biphenyl) of 40 nm in thickness, as the hole injection layer, was disposed on the first electrode. NPD(4,4′-bis[N-(1-naphthyl)-N-phenyl-amino]biphenyl) of 30 nm in thickness, as the hole transport layer, was disposed on the first electrode. A blue light-emitting layer having a thickness of 25 nm was disposed on the hole transport layer by mixing perylene having a concentration of 2 wt % (i.e., a dopant material) in DPVBi(4,4′-bis(2,2′-diphenyl vinyl)-1,1′-biphenyl) (i.e., a host material). Alq3(8-hydroxyquinoline aluminum) of 20 nm in thickness, as the electron transport layer, was disposed on the hole transport layer.

The electron injection layer of 10 nm in thickness was formed by mixing Alq3(8-hydroxyquinoline aluminum) and LiF at a ratio of 4:1 by means of a vacuum deposition method. An Al film of 150 nm in thickness, as the second electrode, was formed, and an Al film of 1000 angstrom in thickness was disposed on the MgAg film.

### COMPARATIVE EXAMPLE 1

A process condition of this comparative example was the same as that of the experimental example 1 except that the electron injection layer was formed of Alq3(8-hydroxyquinoline aluminum).

### EXPERIMENTAL EXAMPLE 2

A process condition of this experimental example was the same as that of the experimental example 1 except that a red light-emitting layer of 25 nm in thickness was formed by mixing PIQIr(acac)(bis(1-phenylisoquinoline)acetylacetonate iridium) having a concentration of 2 wt % (i.e., a dopant material) in CBP(carbazole biphenyl) (i.e., a host material).

### COMPARATIVE EXAMPLE 2

A process condition of this comparative example was the same as that of the experimental example 2 except that the electron injection layer was formed of Alq3(8-hydroxyquinoline aluminum).

### EXPERIMENTAL EXAMPLE 3

A process condition of this experimental example was the same as that of the experimental example 1 except that a green light-emitting layer of 25 nm in thickness was formed by mixing Ir(ppy)3(fac tris(2-phenylpyridine)iridium) having a concentration of 2 wt % (i.e., a dopant material) in CBP(carbazole biphenyl) (i.e., a host material).

### COMPARATIVE EXAMPLE 3

A process condition of this comparative example was the same as that of the experimental example 3 except that the electron injection layer was formed of Alq3(8-hydroxyquinoline aluminum).

Driving voltages, emission efficiency, and luminance of the organic light emitting devices, which were fabricated according to the experimental examples 1, 2, and 3 and the comparative examples 1, 2, and 3, were measured, and the results of the measurement are listed in Table 1.

TABLE 1

| | Experi- | Com- | Experi- | Com- | Experi- | |
|---|---|---|---|---|---|---|
| | mental | parative | mental | parative | mental | Com- |
| | example | example | example | example | example | parative |
| | 1 | 1 | 2 | 2 | 3 | example 3 |
| Driving | 5.5 | 6.9 | 5.4 | 7.7 | 5.4 | 7.0 |
| voltage | | | | | | |
| (V) | | | | | | |
| Emission | 5.2 | 2.0 | 17.8 | 16.3 | 33.3 | 24.2 |
| efficiency | | | | | | |
| (cd/A) | | | | | | |
| Luminance | 3.0 | 1.3 | 9.4 | 6.7 | 19.4 | 10.8 |
| (lm/w) | | | | | | |

From the table 1, it can be seen that the organic light emitting device in accordance with an embodiment of this document comprises LiF (i.e., the inorganic material 128) in the electron injection layer and thus has improved driving voltages, emission efficiency, and luminance compared with the organic light emitting device comprising the electron injection layer formed of a conventional organic material 128.

In other words, since the inorganic material is comprised in the electron injection layer, the mobility of electrons can be increased. Accordingly, charge balance of holes and electrons can be poised and efficiency of the organic light emitting device can be improved.

Hereinafter, experimental examples of the organic light emitting device comprising the inorganic material in the hole injection layer (i.e., the organic function layer), which is the closest to the first electrode, of the organic function layers intervened between the first electrode and the emitting layer unlike the above experimental examples 1, 2, and 3 are described.

### EXPERIMENTAL EXAMPLE 4

ITO of 130 nm in thickness, as the first electrode, was disposed on the substrate. NPD(4,4′-bis[N-(1-naphthyl)-N-phenyl-amino]biphenyl) and LiF having a ratio of 4:1, as the hole injection layer, was vacuum deposited to a thickness of 40 nm over the first electrode. NPD(4,4′-bis[N-(1-naphthyl)-N-phenyl-amino]biphenyl) of 30 nm in thickness, as the hole transport layer, was formed. A blue light-emitting layer having a thickness of 25 nm was disposed on the hole transport layer by mixing perylene having a concentration of 2 wt % (i.e., a dopant material) in DPVBi(4,4′-bis(2,2′-diphenyl vinyl)-1,1′-biphenyl) (i.e., a host material). Alq3(8-hydroxyquinoline aluminum) of 20 nm in thickness, as the electron transport layer, was disposed on the hole transport layer.

Alq3(8-hydroxyquinoline aluminum) was deposited to form the electron injection layer of 10 nm in thickness. An Al film of 150 nm in thickness, as the second electrode, was then formed, and an Al film of 1000 angstrom in thickness was disposed on the MgAg film.

### COMPARATIVE EXAMPLE 4

A process condition of this comparative example was the same as that of the experimental example 4 except that the hole injection layer was formed of NPD(4,4′-bis[N-(1-naphthyl)-N-phenyl-amino]biphenyl).

### EXPERIMENTAL EXAMPLE 5

A process condition of this experimental example was the same as that of the experimental example 4 except that a red light-emitting layer of 25 nm in thickness was formed by mixing PIQIr(acac)(bis(1-phenylisoquinoline)acetylacetonate iridium) having a concentration of 2 wt % (i.e., a dopant material) in CBP(carbazole biphenyl) (i.e., a host material).

### COMPARATIVE EXAMPLE 5

A process condition of this comparative example was the same as that of the experimental example 5 except that the hole injection layer was formed of NPD(4,4′-bis[N-(1-naphthyl)-N-phenyl-amino]biphenyl).

### EXPERIMENTAL EXAMPLE 6

A process condition of this experimental example was the same as that of the experimental example 5 except that a green light-emitting layer of 25 nm in thickness was formed by mixing Ir(ppy)3(fac tris(2-phenylpyridine)iridium) having a concentration of 2 wt % (i.e., a dopant material) in CBP(carbazole biphenyl) (i.e., a host material).

### COMPARATIVE EXAMPLE 6

A process condition of this comparative example was the same as that of the experimental example 6 except that the hole injection layer was formed of NPD(4,4′-bis[N-(1-naphthyl)-N-phenyl-amino]biphenyl).

Driving voltages, emission efficiency, and luminance of the organic light emitting devices, which were fabricated according to the experimental examples 4, 5, and 6 and the comparative examples 4, 5, and 6, were measured, and the results of the measurement are listed in Table 2.

TABLE 2

| | Experi- | Com- | Experi- | Com- | Experi- | |
|---|---|---|---|---|---|---|
| | mental | parative | mental | parative | mental | Com- |
| | example | example | example | example | example | parative |
| | 4 | 4 | 5 | 5 | 6 | example 6 |
| Driving | 5.4 | 7.1 | 5.5 | 7.8 | 5.5 | 7.2 |
| voltage | | | | | | |
| (V) | | | | | | |
| Emission | 5.0 | 2.1 | 16.5 | 15.8 | 31.0 | 22.1 |
| efficiency | | | | | | |
| (cd/A) | | | | | | |
| Luminance | 2.9 | 1.4 | 8.9 | 6.1 | 20.4 | 12.8 |
| (lm/w) | | | | | | |

From the table 2, it can be seen that the organic light emitting device in accordance with an embodiment of this document comprises LiF (i.e., the inorganic material) in the hole injection layer and thus has improved driving voltages, emission efficiency, and luminance compared with the organic light emitting device comprising the hole injection layer formed of a conventional organic material.

In other words, since the inorganic material is comprised in the hole injection layer, the mobility of holes can be increased. Accordingly, charge balance of holes and electrons can be poised and efficiency of the organic light emitting device can be improved.

As described above, the organic light emitting device in accordance with the embodiments of this document comprises an inorganic material in the hole injection layer or the electron injection layer, which is adjacent to the first electrode or the second electrode, of the organic function layers intervened between the first electrode and the second electrode. Accordingly, there is an advantage in that a driving voltage, emission efficiency, and luminance of the organic light emitting device can be improved.

An organic light emitting device may comprise a substrate including a thin film transistor comprising a semiconductor layer, a gate electrode, a source electrode, and a drain electrode, a first electrode disposed on the substrate, organic function layers disposed on the first electrode and comprising an emitting layer, and a second electrode disposed on the organic function layers. An organic function layer adjacent to the second electrode, of the organic function layers, comprises an inorganic material.

According to another embodiment, an organic light emitting device may comprise a substrate including a thin film transistor comprising a semiconductor layer, a gate electrode, a source electrode, and a drain electrode, a first electrode disposed on the substrate, organic function layers disposed on the first electrode and comprising an emitting layer, and a second electrode disposed on the organic function layers. An organic function layer adjacent to the first electrode, of the organic function layers, comprises an inorganic material.

In accordance with one or more of the embodiments described herein, the emitting layer may emit one of a variety of colors. In a case where the emitting layeremits red light, the emitting layer may include a host material including carbazole biphenyl (CBP) or 1,3-bis(carbazol-9-yl (mCP), and may be formed of a phosphorescence material including a dopant material including PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), or PtOEP(octaethylporphyrin platinum) or a fluorescence material including PBD:Eu(DBM)3(Phen) or Perylene.

In the case where the emitting layer emits red light, a highest occupied molecular orbital of the host material may range from 5.0 to 6.5, and a lowest unoccupied molecular orbital of the host material may range from 2.0 to 3.5. A highest occupied molecular orbital of the dopant material may range from 4.0 to 6.0, and a lowest unoccupied molecular orbital of the dopant material may range from 2.4 to 3.5.

In the case where the emitting layer emits green light, the emitting layer includes a host material including CBP or mCP, and may be formed of a phosphorescence material including a dopant material including Ir(ppy)3(fac tris(2-phenylpyridine)iridium) or a fluorescence material including Alq3 (tris(8-hydroxyquinolino)aluminum).

In the case where the emitting layer emits green light, a highest occupied molecular orbital of the host material may range from 5.0 to 6.5, and a lowest unoccupied molecular orbital of the host material may range from 2.0 to 3.5. A highest occupied molecular orbital of the dopant material may range from 4.5 to 6.0, and a lowest unoccupied molecular orbital of the dopant material may range from 2.0 to 3.5.

In the case where the emitting layer emits blue light, the emitting layer includes a host material including CBP or mCP, and may be formed of a phosphorescence material including a dopant material including (4,6-F2 ppy)2Irpic or a fluorescence material including spiro-DPVBi, spiro-6P, distyryl-benzene (DSB), distyryl-arylene (DSA), PFO-based polymers, PPV-based polymers, or a combination thereof.

In the case where the emitting layer emits blue light, a highest occupied molecular orbital of the host material may range from 5.0 to 6.5, and a lowest unoccupied molecular orbital of the host material may range from 2.0 to 3.5. A highest occupied molecular orbital of the dopant material may range from 4.5 to 6.0, and a lowest unoccupied molecular orbital of the dopant material may range from 2.0 to 3.5.

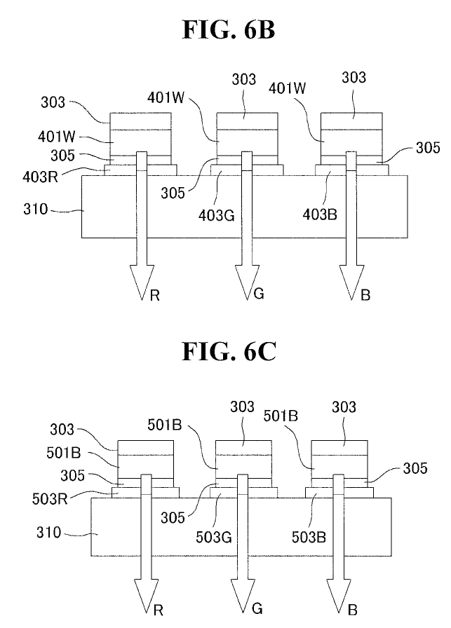

Additional embodiments relating to various color image display methods in an organic light emitting device will now be described with reference to FIGS. 6A to 6C.

FIGS. 6A to 6C illustrate various implementations of a color image display method in an organic light emitting device according to one exemplary embodiment.

First, FIG. 6A illustrates a color image display method in an organic light emitting device separately including a red organic function layers 301R a green organic function layers 301G and a blue organic function layers 301B which emit red, green and blue light, respectively.

The red, green and blue light produced by the red, green and blue organic function layers 301R, 301G and 301B is mixed to display a color image.

It may be understood in FIG. 6A that the red, green and blue organic function layers 301R, 301G and 301B each include an electron transport layer, an emitting layer, a hole transport layer, and the like. In FIG. 6A, a reference numeral 303 indicates a cathode electrode, 305 an anode electrode, and 310 a substrate. It is possible to variously change a disposition and a configuration of the cathode electrode, the anode electrode and the substrate.

FIG. 6B illustrates a color image display method in an organic light emitting device including a white organic function layers 401W, a red color filter 403R, a green color filter 403G and a blue color filter 403B. And the organic light emitting device further may include a white color filter (not shown).

As illustrated in FIG. 6B, the red color filter 403R, the green color filter 403G and the blue color filter 403B each transmit white light produced by the white organic function layers 401W to produce red light, green light and blue light. The red, green and blue light is mixed to display a color image.

It may be understood in FIG. 6B that the white organic function layers 401W includes an electron transport layer, an emitting layer, a hole transport layer, and the like.

FIG. 6C illustrates a color image display method in an organic Light emitting device including a blue organic function layers 501B, a red color change medium 503R and a green color change medium 503G.

As illustrated in FIG. 6C, the red color change medium 503R and the green color change medium 503G each transmit blue light produced by the blue organic emitting function layers 501B to produce red light, green light and blue light. The red, green and blue light is mixed to display a color image.

It may be understood in FIG. 6C that the blue organic function layers 501B includes an electron transport layer, an emitting layer, a hole transport layer, and the like.

A difference between driving voltages, e.g., the power voltages VDD and Vss of the organic light emitting device may change depending on the size of the display panel 100 and a driving manner. A magnitude of the driving voltage is shown in the following Tables 1 and 2. Table 1 indicates a driving voltage magnitude in case of a digital driving manner, and Table 2 indicates a driving voltage magnitude in case of an analog driving manner.

TABLE 1

| Size (S) of | | | |
|---|---|---|---|
| display panel | VDD-Vss (R) | VDD-Vss (G) | VDD-Vss (B) |
| S < 3 inches | 3.5-10 (V) | 3.5-10 (V) | 3.5-12 (V) |
| 3 inches < | 5-15 (V) | 5-15 (V) | 5-20 (V) |
| S < 20 inches | | | |
| 20 inches < S | 5-20 (V) | 5-20 (V) | 5-25 (V) |

TABLE 2

| Size (S) of display panel | VDD-Vss (R, G, B) |
|---|---|
| S < 3 inches | 4~20 (V) |
| 3 inches < S < 20 inches | 5~25 (V) |
| 20 inches < S | 5~30 (V) |

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An organic light emitting device, comprising:
a substrate including a thin film transistor comprising a semiconductor layer, a gate electrode, a source electrode, and a drain electrode:
a first electrode disposed on the substrate;
organic function layers disposed on the first electrode and comprising an emitting layer; and
a second electrode disposed on the organic function layers, wherein an organic function layer adjacent to one of the first electrode or the second electrode includes an inorganic material.

2. The organic light emitting device of claim 1, wherein the organic function layer including the inorganic material is adjacent to the first electrode.

3. The organic light emitting device of claim 1, wherein the organic function layer including the inorganic material is adjacent to the second electrode.

4. The organic light emitting device of claim 1, wherein the inorganic material includes a metal compound.

5. The organic light emitting device of claim 4, wherein the metal compound includes an alkali metal or an alkaline earth metal.

6. The organic light emitting device of claim 5, wherein the metal compound comprising the alkali metal or the alkaline earth metal includes LiQ, LiF, NaF, KF, RbF, CsF, FrF, BeF₂, MgF₂, CaF₂, SrF₂, BaF₂, or RaF₂.

7. The organic light emitting device of claim 1, wherein the organic function layer adjacent to the second electrode includes an electron injection layer or an electron transport layer.

8. The organic light emitting device of claim 1, wherein a hole transport layer or a hole injection layer is included between the first electrode and the emitting layer.

9. The organic light emitting device of claim 1, wherein a thickness of the organic function layer comprising the inorganic material is thinner than a thickness of any one of the remaining organic function layers.

10. The organic light emitting device of claim 1, wherein a highest level of a valence band of the inorganic material is higher than a highest level of a valence band of the remaining organic function layers.

11. The organic light emitting device of claim 1, wherein a highest level of a valence band of the inorganic material is higher than a highest level of a valence band of the emitting layer, but lower than a lowest level of a conduction band of the emitting layer.

12. An organic light emitting device comprising:
a substrate including a thin film transistor comprising a semiconductor layer, a gate electrode, a source electrode, and a drain electrode:
a first electrode disposed on the substrate;
organic function layers disposed on the first electrode and comprising an emitting layer; and
a second electrode disposed on the organic function layers, wherein an organic function layer adjacent to one of the first electrode or the second electrode includes an inorganic material and wherein the emitting layer includes a phosphorescence material.

13. The organic light emitting device of claim 12, wherein the emitting layer includes a fluorescent material.

14. The organic light emitting device of claim 12, wherein the organic function layer including the inorganic material is adjacent to the first electrode.

15. The organic light emitting device of claim 12, wherein the organic function layer including the inorganic material is adjacent to the second electrode.

16. An organic light emitting device, comprising:
a substrate including a thin film transistor comprising a semiconductor layer, a gate electrode, a source electrode, and a drain electrode:
a first electrode disposed on the substrate;
organic function layers disposed on the first electrode and comprising an emitting layer; and
a second electrode disposed on the organic function layers, wherein an organic function layer adjacent to one of the first electrode or the second electrode includes an inorganic material, and wherein a highest level of a valence band of the inorganic material is higher than a highest level of a valence band of the organic function layer including the inorganic material.

17. The organic light emitting device of claim 16, wherein said organic function layer including the inorganic material is adjacent to the first electrode.

18. The organic light emitting device of claim 16, wherein said organic function layer including the inorganic material is adjacent to the second electrode.

19. An organic light emitting device, comprising:
a substrate including a thin film transistor comprising a semiconductor layer, a gate electrode, a source electrode, and a drain electrode:
a first electrode disposed on the substrate;
organic function layers disposed on the first electrode and comprising an emitting layer; and
a second electrode disposed on the organic function layers, wherein an organic function layer adjacent to one of the first electrode or the second electrode includes an inorganic material, and wherein a highest level of a valence band of the inorganic material is lower than a lowest level of a conduction band of the organic function layer including the inorganic material.

20. The organic light emitting device of claim 19, wherein said organic function layer including the inorganic material is adjacent to the first electrode.

21. The organic light emitting device of claim 19, wherein said organic function layer including the inorganic material is adjacent to the second electrode.

22. An organic light emitting device, comprising:
a substrate including a thin film transistor comprising a semiconductor layer, a gate electrode, a source electrode, and a drain electrode:
a first electrode disposed on the substrate;
organic function layers disposed on the first electrode and comprising an emitting layer; and
a second electrode disposed on the organic function layers, wherein an organic function layer adjacent to one of the first electrode or the second electrode includes an inorganic material and wherein the inorganic material is dispersed in the organic function layer.

23. The organic light emitting device of claim 22, wherein said organic function layer including the inorganic material is adjacent to the first electrode.

24. The organic light emitting device of claim 22, wherein said organic function layer including the inorganic material is adjacent to the second electrode.

25. The organic light emitting device of claim 22, wherein a gap between particles of the inorganic material lies substantially in a range between 5 and 45 angstrom.
